(19) United States
(12) Patent Application Publication
(10) Pub. No.: US 2025/0144747 A1
(43) Pub. Date: May 8, 2025

(54) METHOD OF MANUFACTURING SUBSTRATE

(71) Applicant: DISCO CORPORATION, Tokyo (JP)

(72) Inventor: Yuya SETO, Tokyo (JP)

(21) Appl. No.: 18/926,654

(22) Filed: Oct. 25, 2024

(30) Foreign Application Priority Data
Nov. 6, 2023 (JP) 2023-189032

(51) Int. Cl. B23K 26/53; B23K 26/0622; B23K 101/40; H01L 21/304

(52) U.S. Cl. CPC B23K 26/53; B23K 26/0622; H01L 21/304; B23K 2101/40

(57) ABSTRACT

A method of manufacturing a substrate from a workpiece includes a separation layer forming step of moving the workpiece and a focused spot of a laser beam having a wavelength transmittable through the gallium oxide and a repetitively pulsed power output relatively to each other perpendicularly to thicknesswise directions of the workpiece while positioning the focused spot within the workpiece, thereby forming in the workpiece a separation layer including a plurality of modified regions arrayed in a direction along which the focused spot travels in the workpiece and cracks developed from each of the modified regions, and after the separation layer forming step, a cleaving step of cleaving the workpiece along the separation layer, thereby manufacturing the substrate from the workpiece.

### BACKGROUND OF THE INVENTION

### Field of the Invention

The present invention relates to a method of manufacturing a substrate from a workpiece made of gallium oxide such that the substrate is thinner than the workpiece.

### Description of the Related Art

Gallium oxide (Ga₂O₃) is a wide-gap semiconductor having a band gap of approximately 4.8 eV (see, for example, JP 2007-254174A). Therefore, gallium oxide is expected to produce therefrom a substrate that is used to construct semiconductor devices such as power devices, for example, thereon. Such a substrate is fabricated from a cylindrical workpiece called “ingot” by slicing the workpiece with a wire saw, for example (see, for example, JP 2016-13929A).

### SUMMARY OF THE INVENTION

Semiconductor devices are constructed on a substrate having a thickness of approximately 150 μm, for example. A wire saw that is used to slice a cylindrical workpiece into substrates has a thickness of approximately 300 μm, for example. Therefore, when substrates are fabricated from a cylindrical workpiece with use of the wire saw, as much workpiece material as 60% to 70% of the entire workpiece is discarded as saw dust, resulting in an undue reduction in productivity.

It is therefore an object of the present invention to provide a method of manufacturing a substrate with increased productivity from a workpiece made of gallium oxide such that the substrate is thinner than the workpiece.

In accordance with an aspect of the present invention, there is provided a method of manufacturing a substrate from a workpiece made of gallium oxide such that the substrate is thinner than the workpiece. The method includes a separation layer forming step of moving the workpiece and a focused spot of a laser beam having a wavelength transmittable through the gallium oxide and a repetitively pulsed power output relatively to each other perpendicularly to thicknesswise directions of the workpiece while positioning the focused spot within the workpiece, thereby forming in the workpiece a separation layer including a plurality of modified regions arrayed in a direction along which the focused spot travels in the workpiece and cracks developed from each of the plurality of modified regions, and after the separation layer forming step, a cleaving step of cleaving the workpiece along the separation layer, thereby manufacturing the substrate from the workpiece, in which a value calculated by dividing a center-to-center spacing of an adjacent pair of modified regions in the direction along which the focused spot travels among the plurality of modified regions by a length of modified region of each of the adjacent pair in the direction along which the focused spot travels is in a range of 1.63 to 2.73.

Preferably, a value is in the range of 1.94 to 2.43. More preferably, the value is in the range of 2.11 to 2.33.

In addition, the method of manufacturing a substrate should preferably further include a preliminary modified region forming step of forming a preliminary modified region in the workpiece by applying to the workpiece a laser beam having the same pulsed energy as the laser beam applied to the workpiece in the separation layer forming step while positioning a focused spot of the laser beam within the workpiece, and after the preliminary modified region forming step but before the separation layer forming step, a measuring step of measuring a reference length of preliminary modified region in the direction along which the focused spot travels, in which conditions for applying the laser beam to the workpiece in the separation layer forming step are established such that the center-to-center spacing is in the range of 1.63 to 2.73 times the reference length of preliminary modified region.

According to the present invention, after a separation layer including a plurality of modified regions and cracks developed from each of the modified regions has been formed in a workpiece, the workpiece is cleaved along the separation layer, and a substrate is thereby manufactured from the workpiece. The method according to the present invention is able to manufacture the substrate from the ingot with higher productivity than a process of manufacturing a substrate from an ingot by slicing the ingot using a wire saw.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically illustrating by way of example an ingot made of gallium oxide;

FIG. 1B is a side elevational view of the ingot illustrated in FIG. 1A;

FIG. 2 is a flowchart schematically illustrating a method of manufacturing a substrate from the ingot illustrated in FIGS. 1A and 1B when the substrate is thinner than the ingot according to an embodiment of the present invention;

FIG. 3 is a perspective view schematically illustrating the manner in which a separation layer forming step of the method illustrated in FIG. 2 is carried out;

FIG. 4 is a plan view schematically illustrating a plurality of modified regions formed in the ingot illustrated in FIGS. 1A and 1B;

FIG. 5 is a graph representing a relation between the length of crack developed from the modified region illustrated in FIG. 4 and value calculated by dividing the spacing between centers of an adjacent pair of modified regions by the length of modified regions;

FIGS. 6A and 6B are side elevational views schematically illustrating the manner in which a cleaving step of the method illustrated in FIG. 2 is carried out; and

FIG. 7 is a flowchart schematically illustrating a method of manufacturing a substrate from the ingot illustrated in FIGS. 1A and 1B when the substrate is thinner than the ingot according to another embodiment of the present invention.

### DETAILED DESCRIPTION OF THE PREFERRED EMBODIMENT

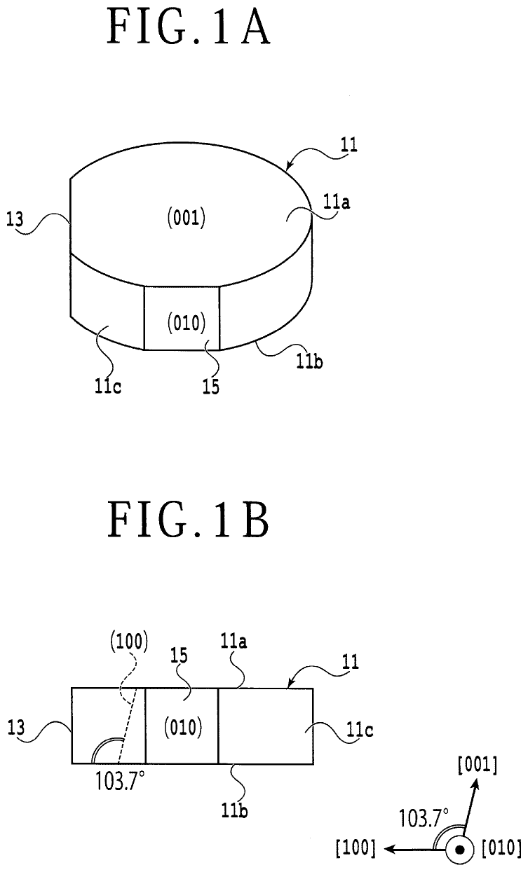

A preferred embodiment of the present invention will be described below with reference to the accompanying drawings. FIG. 1A schematically illustrates, in perspective, an ingot 11 made of gallium oxide, specifically, β-phase gallium oxide, by way of example. FIG. 1B schematically illustrates, in side elevation, the ingot 11 illustrated in FIG. 1A. In FIGS. 1A and 1B, crystal planes of the gallium oxide of the ingot 11 are also illustrated. In FIG. 1B, crystal orientations of the gallium oxide are also illustrated.

The β-phase gallium oxide is of a monoclinic crystal structure in which the angle formed between a crystal orientation [100] (a-axis) and a crystal orientation [100] (c-axis) is 103.7° and each of the angle formed between a crystal orientation [010] (b-axis) and the crystal orientation [100] (a-axis) and the angle formed between the crystal orientation [010] (b-axis) and the crystal orientation [001] (c-axis) is 90°. The ingot 11 illustrated in FIGS. 1A and 1B has a face side 11a and a reverse side 11b that are opposite to each other and lie parallel to each other. The ingot 11 has a crystal plane {001} exposed on each of the face side 11a and the reverse side 11b (the plane exposed on the face side 11a is also referred to as a “crystal plane (001)” for the sake of convenience).

While the ingot 11 is fabricated such that the crystal plane {001} is exposed on each of the face side 11a and the reverse side 11b, a plane that is slightly oblique to the crystal plane {001} may be exposed on each of the face side 11a and the reverse side 11b due to processing errors, for example, that might occur during the fabrication of the ingot 11. Specifically, a plane angularly spaced from the crystal plane {001} by an angle of 1° or smaller may be exposed on each of the face side 11a and the reverse side 11b.

The ingot 11 has a side face 11c including two flat areas, i.e., a primary orientation flat 13 and a secondary orientation flat 15, representing crystal orientations of gallium oxide. The primary orientation flat 13 is longer than the secondary orientation flat 15, and is positioned in the crystal orientation [φ] as viewed from the center of the ingot 11.

The secondary orientation flat 15 is positioned in the crystal orientation [010] as viewed from the center of the ingot 11. Stated otherwise, the secondary orientation flat 15 is formed as a flat surface where the crystal plane (010) is exposed. The crystal plane (100) forms an obtuse angle of 103.7° with the face side 11a or the reverse side 11b, and extends perpendicularly to the secondary orientation flat 15.

The side face 11c of the ingot 11 may be free of one or both of the primary orientation flat 13 and the secondary orientation flat 15. The side face 11c of the ingot 11 may have a recess (a notch) representing crystal orientations of gallium oxide, rather than the primary orientation flat 13 and the secondary orientation flat 15.

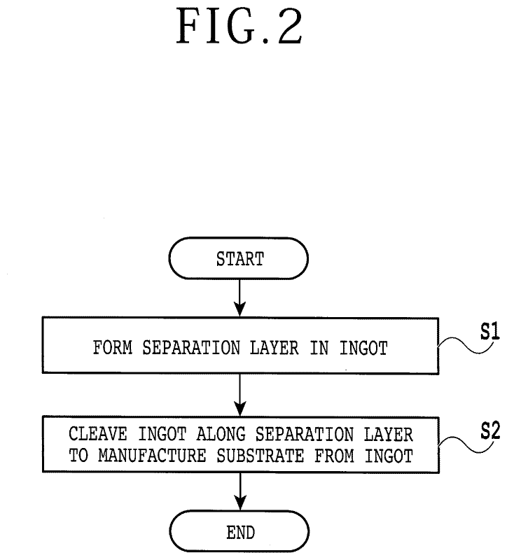

FIG. 2 is a flowchart schematically illustrating a method of manufacturing a substrate from the ingot 11, i.e., a workpiece, illustrated in FIGS. 1A and 1B when the substrate is thinner than the ingot 11 according to an embodiment of the present invention. In the illustrated method, first, a separation layer is formed in the ingot 11 (separation layer forming step S1).

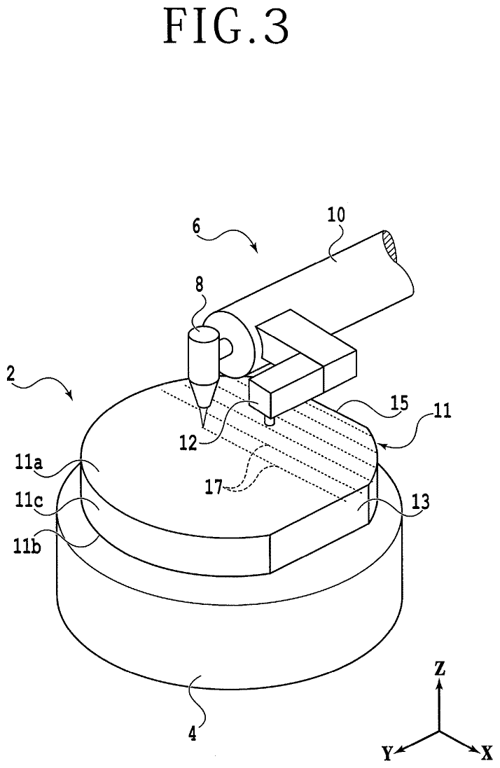

FIG. 3 schematically illustrates, in perspective, the manner in which separation layer forming step S1 is carried out. In FIG. 3, an X-axis and a Y-axis, indicated respectively by arrows X and Y, extend perpendicularly to each other on a horizontal plane, i.e., an XY plane, and a Z-axis, indicated by an arrow Z, extends vertically perpendicularly to the X-axis and the Y-axis. The X-axis, the Y-axis, and the Z-axis will be referred to with respect to a laser processing apparatus 2 that is used to carry out separation layer forming step S1.

The laser processing apparatus 2 that carries out separation layer forming step S1 includes a chuck table 4 for holding the ingot 11 on a holding surface thereof that is of a circular shape and lies generally parallel to the horizontal plane.

The chuck table 4 is fluidly connected to a suction mechanism, not depicted. The suction mechanism has a suction source such as an ejector, for example. When the suction mechanism is actuated, it generates and transmits a suction force, i.e., a negative pressure, to the chuck table 4 where the suction force acts in a space near the holding surface thereof. Therefore, if the ingot 11 is placed on the holding surface of the chuck table 4 when the suction mechanism is actuated, the ingot 11 is held under suction on the holding surface of the chuck table 4.

The chuck table 4 is operatively coupled to a rotating mechanism, not depicted. The rotating mechanism has an electric motor, a pulley coupled to the output shaft of the electric motor, another pulley coupled to the chuck table 4, and an endless belt trained around the pulley, for example. When the electric motor is energized, it generates and transmits rotary power through the pulleys and the endless belt to the chuck table 4, rotating the chuck table 4 about a central axis thereof that extends along the Z-axis. For example, the rotating mechanism turns the chuck table 4 about its central axis until the secondary orientation flat 15 of the ingot 11 held on the holding surface of the chuck table 4 extends parallel to the X-axis.

The laser processing apparatus 2 also includes a laser beam applying unit 6 having a head 8 disposed above the chuck table 4. The head 8 is mounted on a distal end of a tubular housing 10 that extends along the Y-axis. The head 8 houses therein an optical system including, not depicted, a condensing lens, e.g., a condensing lens having a numerical aperture (NA) of 0.85, and a mirror, for example, whereas the housing 10 houses therein an optical system, not depicted, including a mirror and/or a lens, for example.

The housing 10 has a proximal end coupled to a moving mechanism, not depicted. The moving mechanism includes a ball-screw mechanism and an electric motor coupled to the ball-screw mechanism. When the moving mechanism is actuated, it moves the housing 10 along the X-axis, the Y-axis, and/or the Z-axis. The laser beam applying unit 6 also has a laser oscillator, not depicted, including a laser medium of Nd:YAG, for example.

The laser oscillator generates a laser beam having a wavelength of 1064 nm, for example, that is transmittable through the β-phase gallium oxide. The laser beam has a repetitively pulsed power output. For example, the laser beam has a frequency of 30 kHz and a pulse duration of 4 ns. The laser beam emitted from the laser oscillator has its power output regulated by an attenuator, not depicted, and then is directed through the optical systems housed in the housing 10 and the head 8 downwardly toward the ingot 11 on the chuck table 4.

An image capturing unit 12 that is capable of capturing an image of an area directly therebelow is mounted on a side surface of the housing 10 adjacent to the head 8 along the X-axis. The image capturing unit 12 has a light source such as a light-emitting diode (LED) for emitting light, e.g., visible light, of a wavelength transmittable through the β-phase gallium oxide, an objective lens, and an image capturing device such as a charge-coupled-device (CCD) image sensor or a complementary-metal-oxide-semiconductor (CMOS) image sensor, for example.

For carrying out separation layer forming step S1 on the laser processing apparatus 2, first, the ingot 11 is placed on the holding surface of the chuck table 4 with the face side 11a facing upwardly. Then, the suction mechanism is actuated to hold the ingot 11 under suction on the holding surface of the chuck table 4. Thereafter, the image capturing unit 12 is energized to capture an image of the face side 11a of the ingot 11.

Then, the rotating mechanism turns the chuck table 4 about its central axis until the secondary orientation flat 15 of the ingot 11 extends parallel to the X-axis, for example, by referring to the captured image. Specifically, the rotating mechanism turns the chuck table 4 about its central axis until the crystal orientation of the β-phase gallium oxide extends parallel to the X-axis and the crystal orientation [010] thereof extends along the Y-axis.

Then, the moving mechanism moves the housing 10 along the X-axis and/or the Y-axis until a region of the ingot 11 that is positioned slightly radially inwardly from the secondary orientation flat 15 is positioned in a direction along the X-axis as viewed from the head 8. Then, the moving mechanism moves the housing 10 along the Z-axis until the laser beam emitted from the head 8 has its focused spot positioned within the ingot 11.

Then, the moving mechanism moves the housing 10 along the X-axis at a predetermined speed, i.e., a predetermined processing feed speed, to cause the focused spot of the laser beam to travel from one end to the other of the ingot 11 along the X-axis while the laser beam is being emitted from the head 8. In other words, the laser beam is applied to the ingot 11 while scanning the ingot 11 in a direction along the X-axis, i.e., the crystal orientation [100] of the β-phase gallium oxide.

The laser beam thus applied to the ingot 11 imparts its pulsed energy to each of a plurality of sites in the ingot 11 that are arrayed along the X-axis in alignment with the focused spot of the laser beam formed with the repetitively pulsed power output. As a result, a plurality of regions where the crystal structure of the β-phase gallium oxide is disrupted, i.e., a plurality of modified regions 17, are formed respectively around those sites in the ingot 11. The modified regions 17 formed in the ingot 11 are arrayed in a direction along the X-axis along which the focused spot of the laser beam travels in the ingot 11.

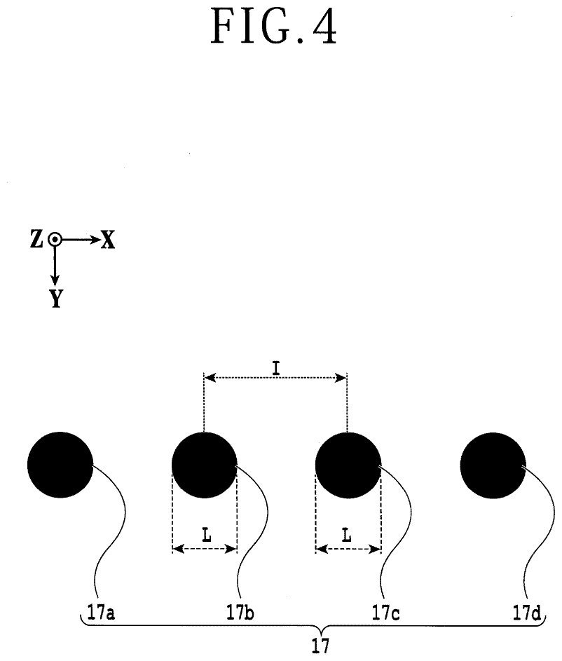

FIG. 4 schematically illustrates, in plan, the modified regions 17 thus formed in the ingot 11. In FIG. 4, four circular modified regions 17a, 17b, 17c and 17d are illustrated in plan for the sake of convenience. However, modified regions 17a, 17b, 17c and 17d that are noncircular in shape, e.g., elliptical in shape, as viewed in plan, may be formed in the ingot 11.

When the modified regions 17 are formed in the ingot 11, a volume of the ingot 11 is expanded, giving rise to internal stresses in the ingot 11. The internal stresses are relaxed by cracks developed in the ingot 11 from each of the modified regions 17. As a consequence, the modified regions 17 arrayed along the X-axis, i.e., along the crystal orientation [φ] of the β-phase gallium oxide, and the cracks developed from each of the modified regions 17 are formed in the ingot 11.

If the spacing I between the centers, also referred to as “center-to-center spacing I,” of an adjacent pair of the modified regions 17, e.g., the modified region 17b and the modified region 17c in FIG. 4, along the X-axis is too short or too long, then the cracks formed in the ingot 11 tend to be short. In this case, the components along the Y-axis of the cracks developed from each of the modified regions 17 also tend to be small.

Specifically, if the center-to-center spacing I is too short, then since most of the internal stresses are released by cracks developed to interconnect the modified regions 17b and 17c, the cracks formed in the ingot 11 are liable to become short. On the other hand, if the center-to-center spacing I is too long, then since only internal stresses produced by the formation of each modified region, e.g., the modified region 17b, contribute to the formation of cracks developed from the modified region 17b, i.e., the internal stresses produced by the formation of the modified regions 17a and 17c adjacent to the modified region 17b do not affect the cracks, the cracks developed from the modified region 17b are liable to become short.

Moreover, if the pulsed energy of the laser beam increases, then the size of each of the modified regions 17b and 17c, e.g., a length L thereof along the X-axis, increases, and so do the internal stresses produced respectively around the modified regions 17b and 17c. If these internal stresses produced around the modified regions 17b and 17c increase, then the cracks are less liable to become short even though the center-to-center spacing I is long. On the other hand, if the center-to-center spacing I is short, then the cracks are liable to become short with respect to the length L of each of the modified regions 17b and 17c along the X-axis.

In order to increase the components along the Y-axis of the cracks developed from each of the modified regions 17b and 17c, it is important to set the ratio between the center-to-center spacing I and the length L of each of modified regions 17b and 17c along the X-axis to an appropriate ratio, i.e., to set a value I/L calculated by dividing the center-to-center spacing I by the length L to an appropriate ratio.

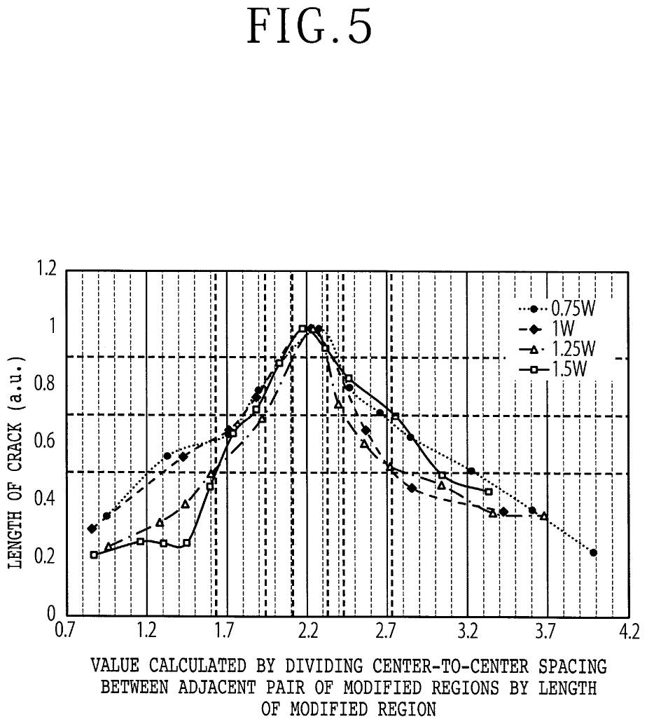

FIG. 5 is a graph representing a relation between the length of crack and the value calculated by dividing the center-to-center spacing I by the length L. Specifically, the graph of FIG. 5 is based on data obtained by assessing a plurality of modified regions formed in the ingot 11 and cracks developed from each of the modified regions under a plurality of conditions representing different laser beam power output levels and different processing-feed speeds at the time the laser beam is applied to the ingot 11.

The data was obtained when the laser beam had power output levels of 0.75 W, 1 W, 1.25 W, and 1.5 W. FIG. 5 illustrates standardized values of the lengths of the cracks formed in the ingot 11 under each of the conditions, i.e., values calculated by dividing the lengths of the cracks under each of the conditions by the maximum length of cracks (maximum crack length) among a plurality of conditions where the laser beam had the same power output.

As illustrated in FIG. 5, the lengths of the cracks formed in the ingot 11 are maximum when the value I/L is approximately 2.22, 90% or larger of the maximum crack length when the value I/L is in the range of 2.11 to 2.33, 70% or larger of the maximum crack length when the value I/L is in the range of 1.94 to 2.43, and 50% or larger of the maximum crack length when the value I/L is in a range of 1.63 to 2.73.

In view of the above findings, the laser beam is applied to the ingot 11 such that the components along the Y-axis of the cracks developed from each of the modified regions 17 are large. Specifically, the laser beam is applied to the ingot 11 such that the value calculated by dividing the center-to-center spacing between an adjacent pair of modified regions along the X-axis among the modified regions 17 by the length along the X-axis of each of the modified regions is in the range of 1.63 to 2.73, preferably in the range of 1.94 to 2.43, more preferably in the range of 2.11 to 2.33, or most preferably is approximately 2.22.

Then, the moving mechanism moves the housing 10 along the Y-axis by a predetermined distance, i.e., an indexed distance, such that the head 8 is positioned in the direction along the X-axis as viewed from an area that slightly farther from the secondary orientation flat 15 than the area that have already been irradiated with the laser beam.

Then, the laser beam is applied to the ingot 11 in the same manner as described above while scanning the ingot 11 in an opposite direction along the X-axis. The above process of applying the laser beam to the ingot 11 is repeated until the application of the laser beam to an area in the ingot 11 that are farthest from the secondary orientation flat 15 is completed.

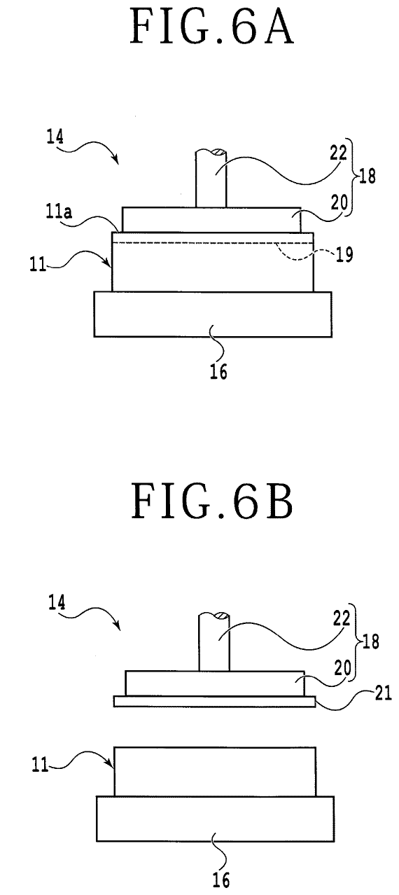

In other words, the relative movement of the ingot 11 and the position where the focused spot of the laser beam is formed, specifically, the movement of the housing 10, along the Y-axis, and the application of the laser beam to the ingot 11 while the laser beam is scanning the ingot 11 in one direction or other along the X-axis are alternately repeated. In this manner, a separation layer 19 (see FIG. 6A) made up of a plurality of areas each including a plurality of modified regions 17 and cracks developed from each of the modified regions 17 is formed in the ingot 11, whereupon separation layer forming step S1 comes to an end.

In separation layer forming step S1 according to the present embodiment, the laser beam scans the ingot 11 in the directions, i.e., one direction and the opposite direction, along the X-axis, parallel to the crystal orientation of the β-phase gallium oxide. However, the laser beam may alternatively scan the ingot 11 in directions not parallel to the crystal orientation [100] of the β-phase gallium oxide.

In separation layer forming step S1, the laser beam may be applied to the ingot 11 while scanning the ingot 11 in only one direction along the X-axis. Specifically, in separation layer forming step S1, the laser beam may be repeatedly applied to the ingot 11 while scanning the ingot 11 in one direction along the X-axis without scanning the ingot 11 in the opposite direction along the X-axis.

In separation layer forming step S1, the laser beam may be applied to the ingot 11 while the focused spot of the laser beam is following a spiral path in the ingot 11. Specifically, the laser beam may be applied to the ingot 11 while the head 8 is moving straight radially inwardly with respect to the ingot 11 to move the focused spot of the laser beam radially inwardly from an outer circumferential edge of the ingot 11 toward the center thereof and at the same time rotating the chuck table 4 with the ingot 11 held thereon about its central axis.

After separation layer forming step S1, the ingot 11 is cleaved along the separation layer to produce a substrate from the ingot 11 (cleaving step S2). FIGS. 6A and 6B schematically illustrate, in side elevation, the manner in which cleaving step S2 is carried out. Cleaving step S2 is carried out on a suction force imposing apparatus 14 illustrated in FIGS. 6A and 6B. The suction force imposing apparatus 14 includes a chuck table 16 that is structurally identical to the chuck table 4 illustrated in FIG. 3.

The chuck table 16 is fluidly connected to a table-side suction mechanism, not depicted. The table-side suction mechanism has a suction source such as a vacuum pump, for example. When the table-side suction mechanism is actuated, it generates and transmits a suction force, i.e., a negative pressure, to the chuck table 16 where the suction force acts in a space near an upper holding surface thereof. Therefore, if the ingot 11 is placed on the holding surface of the chuck table 16 when the table-side suction mechanism is actuated, the ingot 11 is held under suction on the holding surface of the chuck table 16.

The suction force imposing apparatus 14 also includes a separating unit 18 disposed above the chuck table 16. The separating unit 18 has a suction plate 20 having a plurality of suction ports, not depicted, defined in a lower surface thereof. The suction ports are fluidly connected through a suction channel, not depicted, defined in the suction plate 20 to a separating-unit-side suction mechanism, not depicted, including a suction source such as a vacuum pump, for example. When the separating-unit-side suction mechanism is actuated, it generates and transmits a suction force, i.e., a negative pressure, to the suction plate 20 where the suction force acts in a space near a lower holding surface thereof.

The suction plate 20 has an upper surface coupled to a vertically moving mechanism 22. The vertically moving mechanism 22 includes a ball screw and an electric motor operatively connected to the ball screw. When the vertically moving mechanism 22 is actuated, it moves the suction plate 20 vertically.

For carrying out cleaving step S2 on the suction force imposing apparatus 14, while the chuck table 16 and the suction plate 20 are being sufficiently spaced apart from each other, the ingot 11 with the separation layer 19 formed therein is placed on the holding surface of the chuck table 16 with the face side 11a facing upwardly. Then, the table-side suction mechanism is actuated to hold the ingot 11 under suction on the holding surface of the chuck table 16.

Thereafter, the vertically moving mechanism 22 is actuated to lower the suction plate 20 until the lower surface of the suction plate 20 comes into contact with the face side 11a of the ingot 11, as illustrated in FIG. 6A. Then, the separating-unit-side suction mechanism is actuated to enable the suction plate 20 to attract the face side 11a of the ingot 11 upwardly under suction. Then, the vertically moving mechanism 22 lifts the suction plate 20 away from the chuck table 16, as illustrated in FIG. 6B.

Now, external forces are applied to the ingot 11 to separate the face side 11a and the reverse side 11b away from each other, further developing the cracks included in the separation layer 19. As a result, the ingot 11 is cleaved along the separation layer 19, producing a substrate 21 thinner than the ingot 11. Cleaving step S2 is thereby completed, and hence the method of manufacturing a substrate as illustrated in FIG. 2 is completed.

With the method of manufacturing a substrate as illustrated in FIG. 2, the substrate 21 is manufactured from the ingot 11 by forming the separation layer 19 that includes the modified regions 17 and the cracks developed from each of the modified regions 17 in the ingot 11 and then cleaving the ingot 11 along the separation layer 19. The method is able to manufacture the substrate 21 from the ingot 11 with higher productivity than a process of manufacturing a substrate from an ingot by slicing the ingot 11 with use of a wire saw.

The method forms the modified regions 17 in the ingot 11 such that the value calculated by dividing the center-to-center spacing between an adjacent pair of modified regions 17 in a direction along which the focused spot of the laser beam travels in the ingot 11, i.e., along the X-axis, among the modified regions 17 by the length along that direction of each of the modified regions 17 is in the range of 1.63 to 2.73. As a result, the indexed distance in separation layer forming step S1 can be increased. The method is thus able to shorten the period of time required to manufacture the substrate 21 from the ingot 11.

The description given above addresses one embodiment of the present invention, and the invention is not limited to the details of above embodiment. In separation layer forming step S1, for example, the ingot 11 and the focused spot of the laser beam may be relatively moved by any of various structures.

For example, separation layer forming step S1 may be carried out by a laser processing apparatus having a moving mechanism for moving the chuck table 4 respectively along the X-axis, the Y-axis, and/or the Z-axis.

Alternatively, separation layer forming step S1 may be carried out by a laser processing apparatus having a laser beam applying unit that includes a scanning optical system capable of changing the direction in which the laser beam is emitted from its head. The scanning optical system includes a galvanoscanner, an acousto-optical device (AOD), and/or a polygon mirror, for example.

In cleaving step S2, ultrasonic vibrations may be applied to the ingot 11 as external forces for cleaving the ingot 11 along the separation layer 19 to produce a substrate 21 from the ingot 11. Specifically, in cleaving step S2, ultrasonic vibrations may be applied to the face side 11a of the ingot 11 instead of or prior to external forces, i.e., suction forces, for separating the face side 11a and the reverse side 11b away from each other.

The workpiece from which to manufacture the substrate 21 may comprise an ingot fabricated from β-phase gallium oxide where a crystal plane, e.g., the crystal plane (100), other than the crystal plane {001} is exposed.

The workpiece from which to manufacture the substrate 21 may be a bare wafer whose thickness is twice through five times the thickness of each of the substrate 21. The bare wafer may be fabricated from the ingot 11 by cleaving the ingot 11 along the separation layer 19 in the same manner as described above. In this case, therefore, the substrate 21 may be manufactured from the ingot 11 by repeating the above method twice.

Alternatively, the workpiece from which to manufacture the substrate 21 may be a device wafer that includes a bare wafer with semiconductor devices constructed on one surface thereof. In this case, the laser beam should preferably be applied to the surface of the device wafer that is free of the semiconductor devices for preventing the semiconductor devices from being adversely affected by the laser beam.

The present invention covers a method of manufacturing a substrate 21 from the ingot 11 when the substrate 21 is thinner than the ingot 11 according to another embodiment of the present invention, after conditions for applying the laser beam to the ingot 11, e.g., the power output of the laser beam and the processing-feed speed, have been obtained.

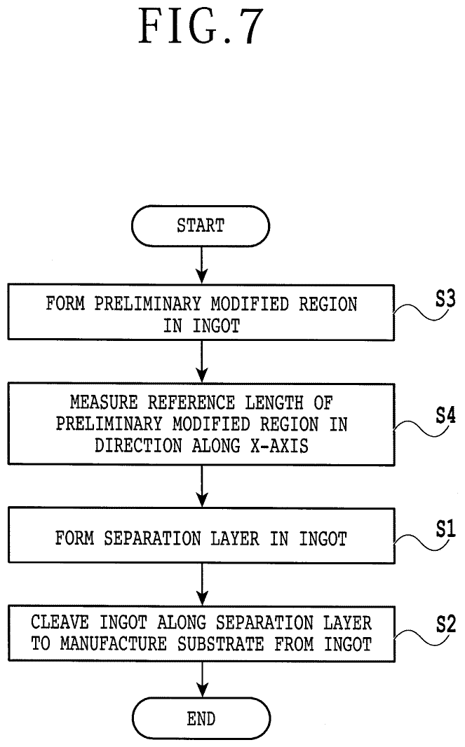

FIG. 7 is a flowchart schematically illustrating the method of manufacturing a substrate according to the other embodiment of the invention. In the method, first, preliminary modified regions are formed in the ingot 11 (preliminary modified region forming step S3). Preliminary modified region forming step S3 is carried out on the laser processing apparatus 2 described above.

For carrying out preliminary modified region forming step S3 on the laser processing apparatus 2, first, the ingot 11 is placed on the holding surface of the chuck table 4 with the face side 11a facing upwardly. Then, the suction mechanism is actuated to hold the ingot 11 under suction on the holding surface of the chuck table 4. Thereafter, the moving mechanism moves the housing 10 along the X-axis and/or the Y-axis until the head 8 is positioned immediately above the ingot 11.

Then, the moving mechanism moves the housing 10 along the Z-axis until the focused spot of the laser beam emitted from the head 8 is positioned at the same height as the focused spot of the laser beam in separation layer forming step S1. Then, the head 8 emits the laser beam toward the ingot 11 with the same pulsed energy as the laser beam applied to the ingot 11 in separation layer forming step S1. The laser beam thus applied forms a preliminary modified region in the ingot 11, whereupon preliminary modified region forming step S3 is completed.

In preliminary modified region forming step S3, only one preliminary modified region or a plurality of preliminary modified regions may be formed in the ingot 11. For forming only one preliminary modified region in the ingot 11, the head 8 may apply a single pulse of laser beam to the ingot 11 without actuating the moving mechanism, for example. For forming a plurality of preliminary modified regions in the ingot 11, the head 8 may apply repetitive pulses of laser beam to the ingot 11 while the moving mechanism is being actuated such that an array of separate, non-overlapping preliminary modified regions will be formed in the ingot 11, for example.

After preliminary modified region forming step S3 but before separation layer forming step S1, a reference length of preliminary modified region in a direction along which the focused spot of the laser beam is to travel with respect to the ingot 11 in separation layer forming step S1, e.g., the direction along the X-axis, is measured (measuring step S4).

In measuring step S4, specifically, the moving mechanism moves the housing 10 along the X-axis and/or the Y-axis to position the image capturing unit 12 directly above the one preliminary modified region or the plurality of preliminary modified regions in the ingot 11. Then, the image capturing unit 12 is energized to capture an image of the one preliminary modified region or the plurality of preliminary modified regions. Then, the reference length is measured by referring to the captured image. Measuring step S4 is now completed.

Measuring step S4 is followed by separation layer forming step S1 and then cleaving step S2. In separation layer forming step S1, conditions for applying the laser beam to the ingot 11, e.g., the processing-feed speed, are established such that the spacing between the centers, e.g., the center-to-center spacing I illustrated in FIG. 4, of an adjacent pair of modified regions 17 in the direction along the X-axis along which the focused spot of the laser beam travels in the ingot 11 among the modified regions 17 is in the range of 1.63 to 2.73 times the reference length, preferably in the range of 1.94 to 2.43 times the reference length, more preferably in the range of 2.11 to 2.33 times the reference length, or most preferably is approximately 2.22 times the reference length.

In this fashion, the components in a direction, e.g., along the Y-axis, perpendicular to the thicknesswise directions of the ingot 11 and the directions along which the focused spot of the laser beam travels in the ingot 11, of the cracks developed from each of the modified regions 17 included in the separation layer 19 formed in the ingot 11 in separation layer forming step S1 can be increased. As a result, the indexed distance in separation layer forming step S1 can be increased. Accordingly, the method of manufacturing a substrate as illustrated in FIG. 7 makes is possible to shorten the period of time required to manufacture the substrate 21 from the ingot 11.

The structural and methodical details of the above embodiment may appropriately be changed or modified without departing from the scope of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of manufacturing a substrate from a workpiece made of gallium oxide such that the substrate is thinner than the workpiece, the method comprising:
a separation layer forming step of moving the workpiece and a focused spot of a laser beam having a wavelength transmittable through the gallium oxide and a repetitively pulsed power output relatively to each other perpendicularly to thicknesswise directions of the workpiece while positioning the focused spot within the workpiece, thereby forming in the workpiece a separation layer including a plurality of modified regions arrayed in a direction along which the focused spot travels in the workpiece and cracks developed from each of the plurality of modified regions; and
after the separation layer forming step, a cleaving step of cleaving the workpiece along the separation layer, thereby manufacturing the substrate from the workpiece, wherein
a value calculated by dividing a center-to-center spacing of an adjacent pair of modified regions in the direction along which the focused spot travels among the plurality of modified regions by a length of modified region of each of the adjacent pair in the direction along which the focused spot travels is in a range of 1.63 to 2.73.

2. The method of manufacturing a substrate according to claim 1, wherein the value is in the range of 1.94 to 2.43.

3. The method of manufacturing a substrate according to claim 1, wherein the value is in the range of 2.11 to 2.33.

4. The method of manufacturing a substrate according to claim 1, further comprising:
a preliminary modified region forming step of forming a preliminary modified region in the workpiece by applying to the workpiece a laser beam having a same pulsed energy as the laser beam applied to the workpiece in the separation layer forming step while positioning a focused spot of the laser beam within the workpiece; and
after the preliminary modified region forming step but before the separation layer forming step, a measuring step of measuring a reference length of preliminary modified region in the direction along which the focused spot travels, wherein
conditions for applying the laser beam to the workpiece in the separation layer forming step are established such that the center-to-center spacing is in the range of 1.63 to 2.73 times the reference length of preliminary modified region.
